(19) United States
(12) Patent Application Publication
(10) Pub. No.: US 2023/0317528 A1
(43) Pub. Date: Oct. 5, 2023

(54) Efficient Semiconductor Metrology Using Machine Learning

(71) Applicant: MELLANOX TECHNOLOGIES, LTD., Yokneam (IL)

(72) Inventors: Juan Jose Vegas Olmos, Solroed Strand (DK); Oscar Mauricio Forero Camacho, Copenhagen (DK); Liran Liss, Atzmon-Segev (IL); Elad Mentovich, Tel Aviv (IL)

(21) Appl. No.: 17/709,458

(22) Filed: Mar. 31, 2022

(51) Int. Cl. H01L 21/66; G06N 3/04; G06N 3/08; G03F 7/20

(52) U.S. Cl. CPC H01L 22/12; G06N 3/04; G06N 3/08; G03F 7/70508; G03F 7/70633; G03F 7/7065; G03F 7/70658

(57) ABSTRACT

A metrology system includes metrology equipment, a remote communication link, a local communication link, and a data processing unit (DPU). The metrology equipment is configured to generate a stream of data relating to inspected wafers, and to format the generated data into first and second data types. The remote communication link is configured to communicate with an external system. The data processing unit (DPU) is configured to (i) using the remote communication link, send the data belonging to the first data type directly to the external system, and (ii) perform analysis on the data belonging to the second data type, and, using the local communication link, provide results of the analysis to the metrology equipment.

### FIELD OF THE INVENTION

The present invention relates generally to devices for accelerating networking processes using artificial intelligence (AI), and specifically to using DPUs to allocate AI workloads in semiconductor metrology systems.

### BACKGROUND OF THE INVENTION

Techniques to perform metrology tasks using AI have been previously proposed in the patent literature. For example, U.S. Pat. No. 10,734,293 describes techniques for measuring and/or compensating for process variations in a semiconductor manufacturing processes. Machine learning algorithms are used on extensive sets of input data, including upstream data, to organize and pre-process the input data, and to correlate the input data to specific features of interest. The correlations can then be used to make process adjustments. The techniques may be applied to any feature or step of the semiconductor manufacturing process, such as overlay, critical dimension, and yield prediction.

### SUMMARY OF THE INVENTION

An embodiment of the present invention that is described herein provides a metrology system including metrology equipment, a remote communication link, a local communication link, and a data processing unit (DPU). The metrology equipment is configured to generate a stream of data relating to inspected wafers, and to format the generated data into first and second data types. The remote communication link is configured to communicate with an external system. The data processing unit (DPU) is configured to (i) using the remote communication link, send the data belonging to the first data type directly to the external system, and (ii) perform analysis on the data belonging to the second data type, and, using the local communication link, provide results of the analysis to the metrology equipment.

In some embodiments, the DPU is configured to perform the analysis on the data belonging to the second data type using a machine learning algorithm.

In some embodiments, the machine learning algorithm is a digital twin type of neural network (NN).

In an embodiment, the second data type includes one or more of: near-line secondary ion mass spectrometry, transmission electron microscopy, optical critical dimension metrology, optical overlay metrology, E-beam overlay metrology, and optical defect inspection.

In some embodiments, the first data type includes one or more of: defect clusters on wafer maps, outliers, and images of electrical power pins.

There is additionally provided, in accordance with another embodiment of the present invention, a metrology method including using metrology equipment, generating a stream of data relating to inspected wafers, the metrology equipment configured to format the generated data into first and second data types. Using a remote communication link, communication with an external system is established. Using the remote communication link with a data processing unit (DPU), the data belonging to the first data type is sent directly to the external system. Analysis is performed using the DPU on the data belonging to the second data type, and, using a local communication link, results of the analysis are provided to the metrology equipment.

The present invention will be more fully understood from the following detailed description of the embodiments thereof, taken together with the drawings in which:

### BRIEF DESCRIPTION OF THE DRAWINGS

FIG. 1 is a block diagram that schematically illustrates an integrated metrology and testing system that incorporates a data processing unit (DPU) and a graphical processing unit (GPU), in accordance with an embodiment of the present invention;

FIG. 2 is a flow chart schematically describing a workflow in a semiconductor foundry with two example areas where the integrated metrology and testing system of FIG. 1 improves yield, in accordance with an embodiment of the present invention;

FIG. 3 is a wafer metrology map comprising a defect pattern that the system of FIG. 1, using AI-driven testing, can identify in-line, in accordance with an embodiment of the present invention; and

FIG. 4 is a flow chart schematically describing a method for selectively providing in-line and offline analysis of semiconductor defects using the system of FIG. 1, in accordance with an embodiment of the present invention.

### DETAILED DESCRIPTION OF EMBODIMENTS

### Overview

The terms artificial intelligence (AI) and machine learning (ML) are used interchangeably in this disclosure. AI and ML serve, in their many derivatives, to quickly process data and identify desired information values (e.g., non-linear patterns in data). Traditionally, such AI processes are run in large infrastructures providing cloud services utilizing clusters of dedicated processors.

However, the explosion of generated data, and hence the congestion of networks, supports the introduction of the data processing unit (DPU) concept. A DPU is a data center unit which typically is in direct local communication with a local processor, such as a graphical processing unit (GPU), capable of AI calculations.

Moreover, the DPU being a sophisticated network adapter, sometimes referred to as a “Smart NIC”, provides additional benefit. Since the DPU is located in the data traffic path to the external system, and performs networking functions for the metrology system, performing the disclosed analysis in the DPU is highly efficient (e.g., yielding less back and forth traffic than a conventional accelerator).

In particular, many metrology and testing steps in the semiconductor industry, currently limited by the aforementioned communications bottlenecks, can benefit from a DPU with a local processor that is very capable of AI-based analysis (e.g., a GPU) or network accelerators. Examples of semiconductor manufacturing processes that can benefit from the introduction of AI-driven analysis locally in metrology include:
Near-line secondary ion mass spectrometry for chemical analysis of 2 nm devices
Transmission electron microscopy for fast imaging
Optical critical dimension metrology for electrical performance analysis
Optical overlay metrology tools with high numerical aperture lenses with a high sampling rate
E-beam overlay metrology
Optical defect inspection

Specifically, semiconductor manufacturing processes require in-line feedback and can no longer rely on static manufacturing processes. Highly complicated and intensive semiconductor processes can benefit from AI-driven metrology of fabrication processes that can adapt and adjust every individual fabrication stage. This in turn increases yield, typically expressed as the number of functional integrated circuits per wafer. DPUs may be an optimal solution for these needs, as a DPU can be placed anywhere within a fab, and in particular included in specific integrated metrology systems.

In some embodiments, a DPU is embedded within metrology or testing equipment. In general, the DPU can be integrated together with the metrology or testing equipment, or it can be connected through it via a high-capacity network interconnect, either Ethernet, Infiniband or any other technology.

The metrology or testing equipment, through a set of sensors, generates a stream of data which is formatted in data blocks. For a general case, two types of data are considered. A first type (referred to as type A) refers to data that needs to be sent directly to an external system (e.g., cloud infrastructure), either for processing, storage or any other activity. A second type (referred to as type B) refers to data that may eventually go to the external system, but which first requires immediate analysis in order to generate in-line feedback for the aforementioned metrology or testing equipment.

Hence, data belonging to the first data type is fast-forwarded to the cloud through accelerated networking. Data belonging to the second data type, on the other hand, is sent to the DPU processing blocks (which may be of a different nature, i.e., a system on chip with processors, GPUs, SCPUs, TPUs, or others). The data is analyzed in the processing blocks, and the outcome is sent back to the metrology and testing equipment as feedback. The analysis results are subsequently sent to the cloud infrastructure.

First data type wafer testing results may include data log files that are saved in a central database, to which AI can be remotely applied for carrying out data exploration, which includes:
detecting defect clusters on wafer maps
detecting failure mechanisms to give faster feedback to the foundry
outlier detection
automatically inking-out units around defect clusters

All of these integrative solutions can be enabled when the edge computing platform (e.g., a DPU and GPU functioning together as described above) is integrated with Fab's metrology equipment.

### System Description

As noted above, acceleration of analysis in defect inspection metrology using local DPUs allows an increase of optical inspection sampling/sensing rate, improved yield with quasi-real time inspection of defects, and reduction of the overall fabrication lead time from wafer-to-die-to-IC. Using local DPUs and GPUs, AI can prove to be valuable to detect delicate patterns of process drifts, which can otherwise be overlooked, so early corrective actions on the process and machinery can be taken.

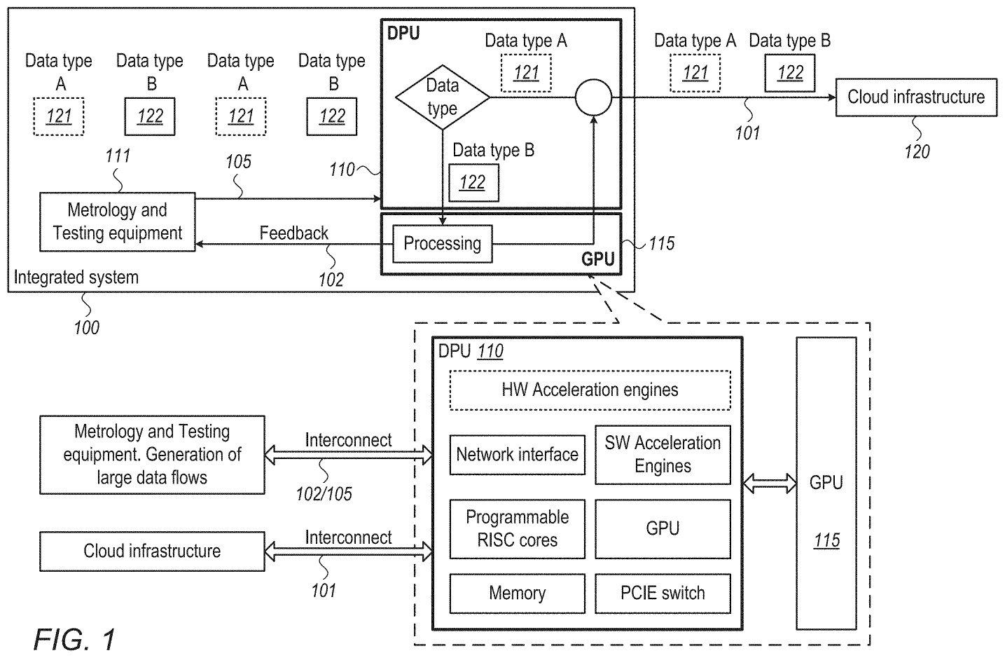

FIG. 1 is a block diagram that schematically illustrates an integrated metrology and testing system 100 that incorporates a data processing unit (DPU) 110 and a graphical processing unit (GPU) 115, in accordance with an embodiment of the present invention.

More generally, system 100 of FIG. 1 may comprise a network adapter (in the present example a DPU 110) and a processor (in the present example a GPU 115). Although the embodiments described below refer mainly to a DPU and a GPU, the disclosed techniques can be implemented using any other suitable network adapter and processor, respectively. In various embodiments, the network adapter may comprise, for example, a DPU (also referred to as a “Smart NIC”), an Ethernet Network Interface Controller (NIC), an Infiniband Host Channel Adapter (HCA), a network-enabled GPU, or any other suitable type of network adapter. The processor may comprise, for example, a GPU, a CPU, or any other suitable type of processor.

As seen in the figure, DPU 110 of system 100 receives metrology and/or test data over a local network link 105, generated in-line by various metrology and testing equipment 111 as a wafer is processed. DPU 110 identifies two types of inspection data, first type 121 (type A) and second type 122 (type B).

DPU 110 first routes data type 121 directly to cloud infrastructure 120, via a remote link 101. At the same time, DPU 110 routes second data type 121 to GPU 115 for analysis by an AI algorithm. The analysis results are provided as feedback over a local network link 102 to the manufacturing machinery to adjust the process. Eventually, the second type of data, together with the feedback, is also routed by DPU to cloud infrastructure 120.

To perform its duties DPU 110 comprises numerous elements, schematically marked in FIG. 1. In various embodiments, the different elements of system 100 shown in FIG. 1 may be implemented using suitable hardware, such as one or more discrete components, one or more Application-Specific Integrated Circuits (ASICs), and/or one or more Field-Programmable Gate Arrays (FPGAs), or in any other suitable way. Some of the functions of DPU 110 and/or GPU 115 may be implemented in one or more general-purpose processors that are programmed in software to carry out the functions described herein. The software may be downloaded to the processors in electronic form, over a network or from a host, for example, or it may, alternatively or additionally, be provided and/or stored on non-transitory tangible media, such as magnetic, optical, or electronic memory.

### Improving Semiconductor Foundry Yield by Using a DPU in Metrology and Testing Systems

System 100 can first train a neural network (NN), or other use another type of machine learning model, to later perform analysis via inference during the fabrication process. The training datasets used for the training can be generated in-house or provided by the foundry. These data sets train neural networks using image processing techniques, the result being a light neural network that can be inferred using the edge computing platform attached to the fabrication equipment and fed with sensors from the machinery to compose a wafer.

For example, a GPU may run a digital twin of the wafer being fabricated, based on the data of the sensors being generated, and the digital twin inferred against the neural network. This allows for active evaluation of wafer status and, potentially, corrections to the fabrication equipment.

If no correction on the fabrication equipment can be conducted, the evaluation of the digital twin can be attached as digital information to the wafer and used by the general availability, testing or validation teams to speed up identification and remedy procedures to increase the yield of individual wafers.

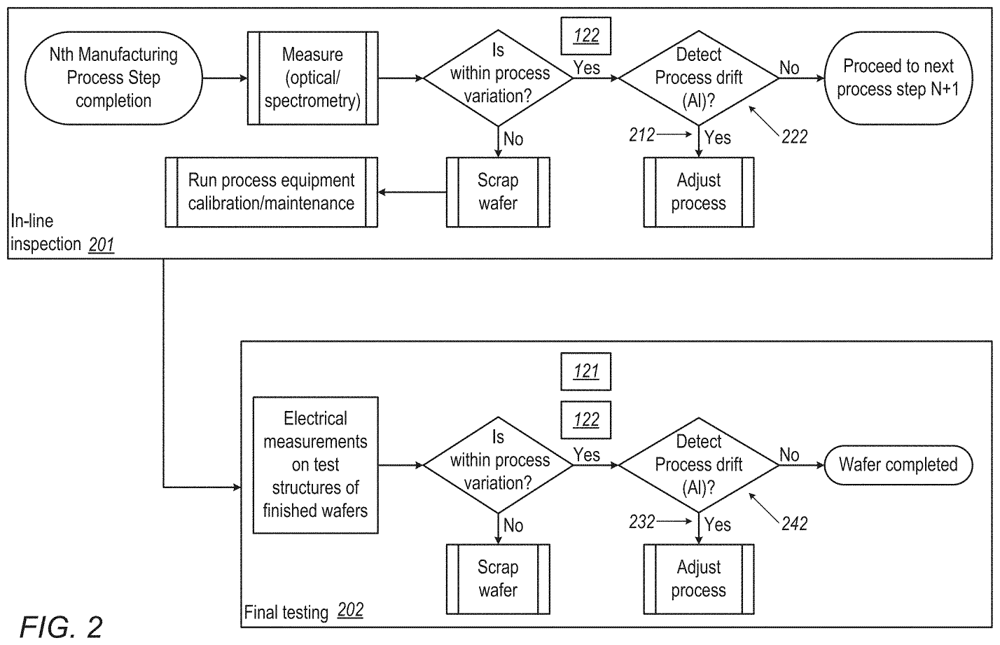

FIG. 2 is a flow chart schematically describing a workflow in a semiconductor foundry with two example areas where the integrated metrology and testing system 100 of FIG. 1 improves yield, in accordance with an embodiment of the present invention.

Block 201 includes an in-line inspections step, typically optical metrology, between an n'th processing step and an (n+1)'th processing step. Accurate and prompt analysis (222) of a second data type (122) received by the DPU is highly beneficial, and a system 100 to perform this task using an AI algorithm can provide (212) the necessary feedback to adjust the n'th processing step as required.

Block 202 includes final testing of finished wavers. For example, when a wafer is completed, it first undergoes electrical measurements on test structures (located in the scribe lines) to maintain resulting process variations within an expected range. Such tests can generate both data types 121 and 122. Depending on data type, system 100 performs analysis (242) of second data type (122) received by the DPU using an AI algorithm and provides (232) the necessary feedback. System 100 transmits first data type 121 to a cloud resource, either for processing, storage, or any other activity.

The finalized wafer can be further visually inspected to detect issues or contamination on top metal layers and on pads/bumps (not shown in the example flowchart of FIG. 2). AI can here prove to be valuable in detecting process drifts, which can otherwise be overlooked, so that early corrective actions on the process and machinery can be taken. These sets of data can also be shared with customers (fabless companies) if requested.

Image processing can also be used just at the moment the wafer's fabrication is completed, for example in the power pins (which are normally silicon carbide). While the wafer is at rest after fabrication, pictures of the pins taken automatically and inferred against a neural network can identify pins susceptible to cracking when powered on. This serves for on-the-spot identification of damaged pins and an estimation of the wafer yield in an area where no remedial procedures can be applied, since power connection failure leads to an automatic discard of the individual integrated circuit.

The neural network can also be trained against values of the machinery (i.e., laser, temperature, vibration, etc.) and measurements taken during the fabrication inferred against this neural network. Should the values be out of range, the neural network can provide an early estimation of the potential for yield reduction.

FIG. 2 shows only one possible embodiment and only a few example tests. In practice there is larger number of tests that system 100 and its like can run in-line and during final testing.

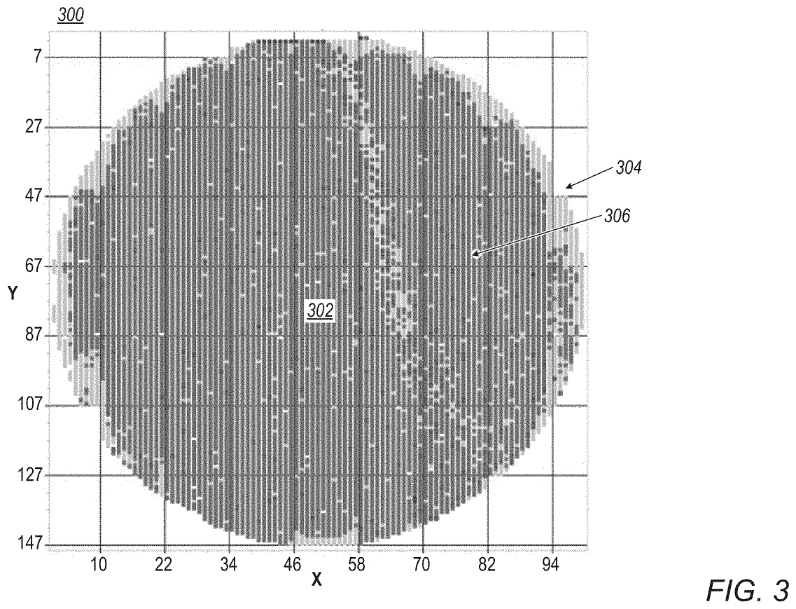

FIG. 3 is a wafer metrology map 300 comprising a second data type (122) including a defect pattern (306) that the system of FIG. 1, using AI-driven testing, can identify in-line, in accordance with an embodiment of the present invention. AI-driven testing by a system 100 during fabrication can identify, at an early state, such a low yield wafer and provide necessary feedback so the process can be adjusted as described in block 201 of FIG. 2.

Specifically, map 300 of a wafer 302 shows a large nonlinear pattern 306 from a lithography process variation (failure following the wafer lithography reticles) and some chemical contamination step (304) caused by a defective machine during processing (right edge). These examples of type two data are suitable for in-line analysis by system 100.

### Method for Selectively Providing In-Line and Offline Analysis of Semiconductor Defects

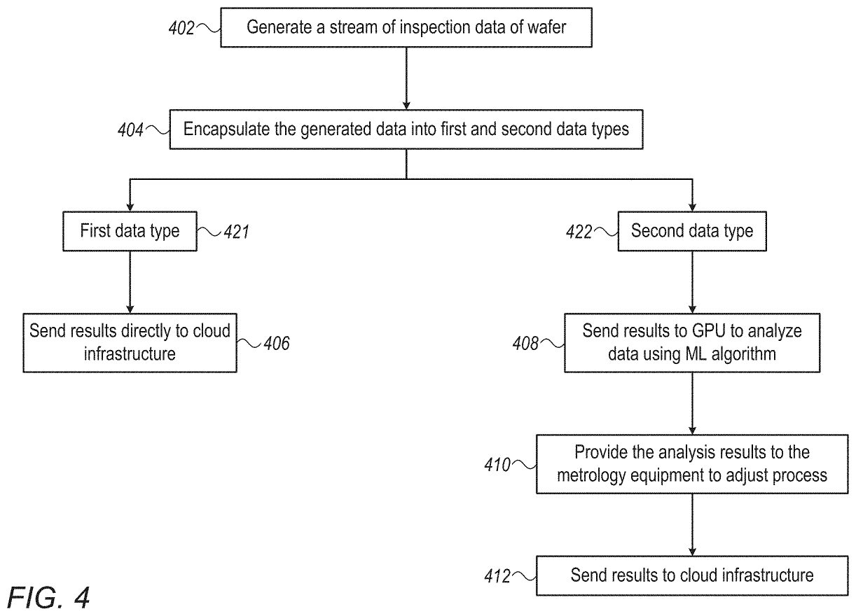

FIG. 4 is a flow chart schematically describing a method for selectively providing in-line and offline analysis of semiconductor defects using system 100 of FIG. 1, in accordance with an embodiment of the present invention. The algorithm according to the presented embodiment carries out a process that begins with metrology or testing equipment generating a stream of inspection data of a wafer, at an inspection step 402.

Next, a processor of the metrology or testing equipment formats the generated data into first data type (421) and second data type (422), e.g., using encapsulation, at data encapsulation step 404.

At first data processing step 406, DPU 110 sends the first data type (421) directly to a cloud resource, either for processing, storage, or any other activity.

At second data processing step 408, DPU 110 sends the second type data (422) to GPU 115 to analyze the data using an AI algorithm, such as analyzing metrology map 300.

At a feedback provision step 410, the DPU sends analysis results (e.g., via data link 102) to the metrology or testing equipment, to adjust the process, for example, to increase yield.

Finally, at cloud transmission step 412, DPU 100 sends the data and the analysis results to a cloud resource, either for processing, storage. or any other activity.

The example flow chart shown in FIG. 4 is brought by example to describe the concept of the shown method embodiment. Other applications may be run using the DPU and GPU, such as for preventive maintenance based on the aforementioned values of the machinery.

Although the embodiments described herein mainly address network communications, the methods and systems described herein can also be used in other applications, such as in deposition of exotic materials on silicon photonics wafer (i.e., silicon carbide or silicon nitrate). In these processes, a chemical vapor deposition process needs to be controlled in relation to temperature, air pressure and/or size of the wafer and variations during the deposition due to mechanical vibrations. The disclosed technique may be utilized to analyze on-the-fly the above data, create a twin model, and figure out in a digital twin if the deposition is progressing as planned even before completing the whole process, hence allowing early discarding.

It will thus be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. A metrology system, comprising:
metrology equipment configured to generate a stream of data relating to inspected wafers, the metrology equipment configured to format the generated data into first and second data types;
a remote communication link configured to communicate with an external system;
a local communication link; and
a data processing unit (DPU) configured to:
using the remote communication link, send the data belonging to the first data type directly to the external system;
perform analysis on the data belonging to the second data type, and, using the local communication link, provide results of the analysis to the metrology equipment.

2. The system according to claim 1, wherein the DPU is configured to perform the analysis on the data belonging to the second data type using a machine learning algorithm.

3. The system according to claim 2, wherein the machine learning algorithm is a digital twin type of neural network (NN).

4. The system according to claim 1, wherein the second data type comprises one or more of:
near-line secondary ion mass spectrometry;
transmission electron microscopy;
optical critical dimension metrology;
optical overlay metrology;
E-beam overlay metrology; and
optical defect inspection.

5. The system according to claim 1, wherein the first data type comprises one or more of:
defect clusters on wafer maps;
outliers; and
images of electrical power pins.

6. A metrology method, comprising:
using metrology equipment, generating a stream of data relating to inspected wafers, the metrology equipment configured to format the generated data into first and second data types;
using a remote communication link, communicating with an external system;
using the remote communication link with a data processing unit (DPU), sending the data belonging to the first data type directly to the external system; and
using the DPU, performing analysis on the data belonging to the second data type, and, using a local communication link, providing results of the analysis to the metrology equipment.

7. The method according to claim 6, wherein performing the analysis on the data belonging to the second data type comprises using a machine learning algorithm.

8. The method according to claim 7, wherein the machine learning algorithm is a digital twin type of neural network (NN).

9. The method according to claim 6, wherein the second data type comprises one or more of:
near-line secondary ion mass spectrometry;
transmission electron microscopy;
optical critical dimension metrology;
optical overlay metrology;
E-beam overlay metrology; and
optical defect inspection.

10. The method according to claim 6, wherein the first data type comprises one or more of:
defect clusters on wafer maps;
outliers; and
images of electrical power pins.
